(19) United States
(12) Patent Application Publication
(10) Pub. No.: US 2024/0312800 A1
(43) Pub. Date: Sep. 19, 2024

(54) SUBSTRATE PROCESSING APPARATUS AND METHOD FOR MANUFACTURING SEMICONDUCTOR DEVICE

(71) Applicant: Kioxia Corporation, Tokyo (JP)

(72) Inventor: Hakuba KITAGAWA, Yokkaichi Mie (JP)

(73) Assignee: Kioxia Corporation, Tokyo (JP)

(21) Appl. No.: 18/592,988

(22) Filed: Mar. 1, 2024

(30) Foreign Application Priority Data
Mar. 14, 2023 (JP) 2023-040058

(51) Int. Cl. H01L 21/67; C25B 1/02; C25D 17/00; H01L 21/687

(52) U.S. Cl. CPC H01L 21/67023; C25B 1/02; C25D 17/001; H01L 21/67253; H01L 21/68707

(57) ABSTRACT

A substrate processing apparatus includes a processing tank configured to accommodate a substrate processing liquid; a holder configured to place a first substrate in the processing tank; an anode and a cathode configured to form a porous layer on a first surface of the first substrate; and a bubble supplier configured to supply a first bubble to the first surface of the first substrate.

### CROSS-REFERENCE TO RELATED APPLICATION

This application is based upon and claims the benefit of priority from Japanese Patent Application No. 2023-040058, filed Mar. 14, 2023, the entire contents of which are incorporated herein by reference.

### FIELD

Embodiments described herein relate generally to a substrate processing apparatus and a method for manufacturing a semiconductor device.

### BACKGROUND

When a porous layer is formed on a surface of a substrate, the porous layer cannot be suitably formed due to various reasons. For example, when a porous layer is formed on the surface of the substrate in a liquid, bubbles adhering to the surface of the substrate hinder the formation of the porous layer.

### DESCRIPTION OF THE DRAWINGS

FIG. 1 is a cross-sectional view (1/3) showing a structure of a substrate processing apparatus according to a first embodiment.

FIG. 2 is a cross-sectional view (2/3) showing the structure of the substrate processing apparatus according to the first embodiment.

FIG. 3 is a cross-sectional view (3/3) showing the structure of the substrate processing apparatus according to the first embodiment.

FIG. 4 is an enlarged cross-sectional view showing the structure of the substrate processing apparatus according to the first embodiment.

FIG. 5 is a perspective view showing a shape of a bubbler tube according to the first embodiment.

FIG. 6 is a cross-sectional view showing the shape of the bubbler tube according to the first embodiment.

FIG. 7 is a cross-sectional view showing a structure of a substrate processing apparatus of a comparative example according to the first embodiment.

FIGS. 8A and 8B are cross-sectional views for comparing the first embodiment with the comparative example.

FIG. 9 is a cross-sectional view showing a structure of a substrate processing apparatus according to a first modification example of the first embodiment.

FIG. 10 is a cross-sectional view showing a structure of a substrate processing apparatus according a second modification example of the first embodiment.

FIG. 11 is a cross-sectional view showing a structure of a semiconductor device according to a second embodiment.

FIG. 12 is an enlarged cross-sectional view showing the structure of the semiconductor device according to the second embodiment.

FIGS. 13A to 13C are cross-sectional views (1/2) showing a method for manufacturing semiconductor device according to the second embodiment.

FIGS. 14A to 14C are cross-sectional views (2/2) showing a method for manufacturing a semiconductor device according to the second embodiment.

FIGS. 15A and 15B are cross-sectional views (1/5) showing a detail of the method for manufacturing the semiconductor device according to the second embodiment.

FIGS. 16A and 16B are cross-sectional views (2/5) showing the detail of the method for manufacturing the semiconductor device according to the second embodiment.

FIGS. 17A and 17B are cross-sectional views (3/5) showing the detail of the method for manufacturing the semiconductor device according to the second embodiment.

FIGS. 18A and 18B are cross-sectional views (4/5) showing the detail of the method for manufacturing the semiconductor device according to the second embodiment.

FIGS. 19A and 19B are cross-sectional views (5/5) showing the detail of the method for manufacturing the semiconductor device according to the second embodiment.

FIG. 20 is a cross-sectional view showing a structure of a semiconductor device according to a modification example of the second embodiment.

### DETAILED DESCRIPTION

Embodiments provide a substrate processing apparatus capable of suitably forming a porous layer on a surface of a substrate, and a method for manufacturing a semiconductor device.

In general, according to one embodiment, a substrate processing apparatus includes a processing tank configured to accommodate a substrate processing liquid; a holder configured to place a first substrate in the processing tank; an anode and a cathode configured to form a porous layer on a first surface of the first substrate; and a bubble supplier configured to supply a first bubble to the first surface of the first substrate.

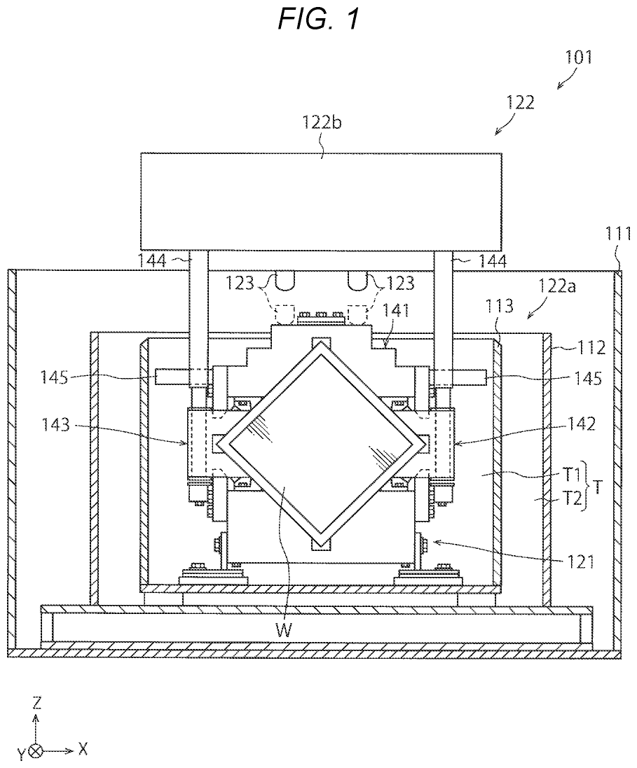

Hereinafter, embodiments of the present disclosure will be described with reference to the drawings. In FIGS. 1 to 20, the same components are denoted by the same reference symbols, and redundant description will be omitted.

### First Embodiment

FIG. 1 to FIG. 3 are cross-sectional views showing a structure of a substrate processing apparatus 101 of a first embodiment.

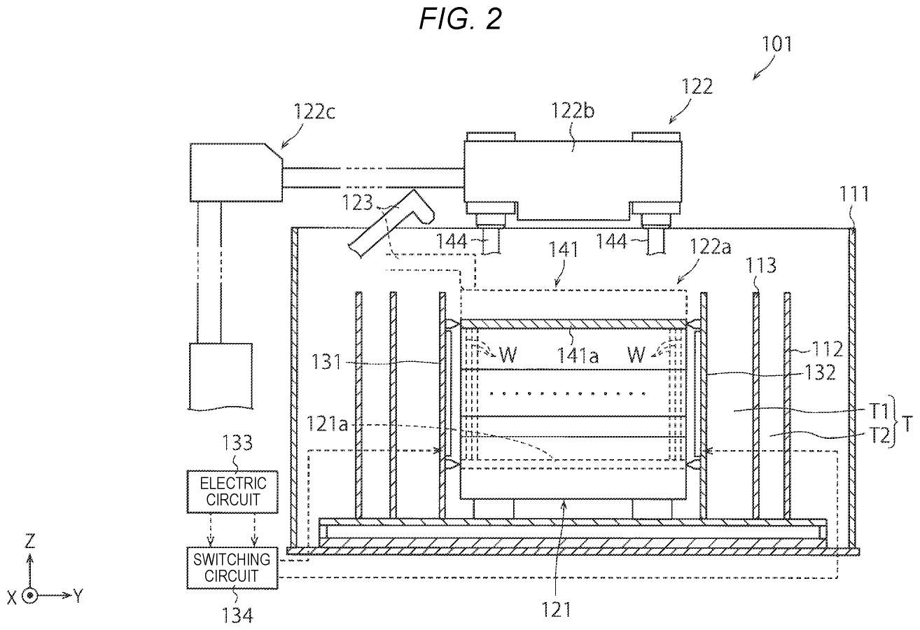

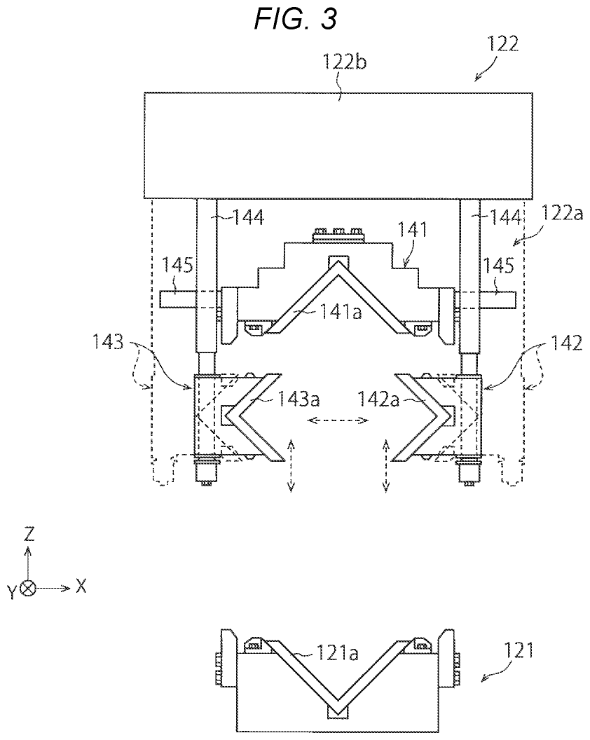

The substrate processing apparatus 101 is an apparatus that processes a substrate W, and is, for example, an anodizing apparatus that forms a porous layer on a surface of the substrate W by an anodizing method. FIG. 1 and FIG. 2 show different vertical cross sections of the substrate processing apparatus 101. FIG. 3 shows a portion of the substrate processing apparatus 101 in detail.

FIG. 1 to FIG. 3 show an X direction, a Y direction, and a Z direction vertical to each other. In this specification, a +Z direction is treated as an upward direction, and a −Z direction is treated as a downward direction. Further, a direction parallel to the Z direction is treated as a vertical direction, and a direction perpendicular to the Z direction is treated as a horizontal direction. The −Z direction may or may not coincide with a gravity direction.

The substrate processing apparatus 101 includes an outer container 111, an inner container 112, a partition wall 113, a lower holder 121, a transfer robot 122, a plurality of pressurizing arms 123, an electrode 131, an electrode 132, an electric circuit 133, and a switching circuit 134. The transfer robot 122 includes an upper holder 122a, a hanging unit 122b, and a moving mechanism 122c, and the upper holder 122a includes an upper side holder 141, a left side holder 142, a right side holder 143, a plurality of suspension arms 144, and a locking bar 145. The lower holder 121, the upper side holder 141, the left side holder 142, and the right side holder 143 include an elastic member 121a, 141a, 142a, and 143a, respectively.

As shown in FIG. 1 and FIG. 2, the inner container 112 is disposed in the outer container 111, and the partition wall 113 is disposed in the inner container 112. As a result, the inner container 112 forms a storage tank T including an inner tank T1 in the partition wall 113 and an outer tank T2 between the partition wall 113 and the inner container 112. The storage tank T stores an electrolytic solution. The electrolytic solution is supplied from a weighing tank (not shown) to the inner tank T1, and the electrolytic solution overflowing from the inner tank T1 through an upper portion of the partition wall 113 is collected in the outer tank T2. It is possible that the inner tank T1 accommodates a plurality of substrates W. A planar shape of these substrates W is, for example, a circle or a quadrangular. The planar shape of the substrate W illustrated in FIG. 1 is a quadrangle. The storage tank T, the electrolytic solution, and the substrate W are an example of a processing tank, a substrate processing liquid, and a first substrate, respectively.

The lower holder 121 is disposed in the inner tank T1. The lower holder 121 holds the plurality of substrates W in the inner tank T1 together with the upper holder 122a of the transfer robot 122. As shown in FIG. 3, the upper holder 122a includes an upper side holder 141, a left side holder 142, and a right side holder 143. Each substrate W is held by being sandwiched between the lower holder 121, the upper side holder 141, the left side holder 142, and the right side holder 143. Each substrate W is held by the lower holder 121, the upper side holder 141, the left side holder 142, and the right side holder 143 such that the substrate W is in contact with the elastic members 121a, 141a, 142a, and 143a.

The transfer robot 122 includes an upper holder 122a, a hanging unit 122b that hangs the upper holder 122a, and the moving mechanism 122c that moves the hanging unit 122b. The transfer robot 122 can move the upper holder 122a in the vertical direction and the horizontal direction by the hanging unit 122b and the moving mechanism 122c. The hanging unit 122b can move the upper side holder 141, the left side holder 142, and the right side holder 143 using the suspension arm 144 and the locking bar 145.

The pressurizing arm 123 presses the upper side holder 141 downward. Accordingly, the lower holder 121 is pressed by the upper side holder 141 via the left side holder 142 and the right side holder 143.

The electrodes 131 and 132 are disposed in the inner tank T1 and are used to electrically process each substrate W held by the lower holder 121 and the upper holder 122a. Each substrate W is held between the electrode 131 and the electrode 132 in the inner tank T1 by the lower holder 121 and the upper holder 122a. The electrodes 131 and 132 can simultaneously process the plurality of substrates W held by the lower holder 121 and the upper holder 122a (batch processing). For example, when the electrode 131 is an anode and the electrode 132 is a cathode, a porous layer can be formed on a surface of each substrate W on a side of the electrode 132 by the anodizing method. The surface of each substrate W on the side of the electrode 132 side is an example of a first surface, and a surface of each substrate W on a side of the electrode 131 is an example of a second surface. Each substrate W is held by the lower holder 121 and the upper holder 122a such that the former surface faces the side of the electrode 132 and the latter surface faces the side of the electrode 131.

The electric circuit 133 applies a voltage to the electrode 131 and the electrode 132. The electric circuit 133 includes, for example, a direct current power source that applies a direct current (DC) voltage to the electrode 131 and the electrode 132.

The switching circuit 134 is disposed between the electric circuit 133 and the electrodes 131 and 132. For example, the switching circuit 134 can switch a polarity of the direct current voltage applied from the electric circuit 133 at a predetermined cycle.

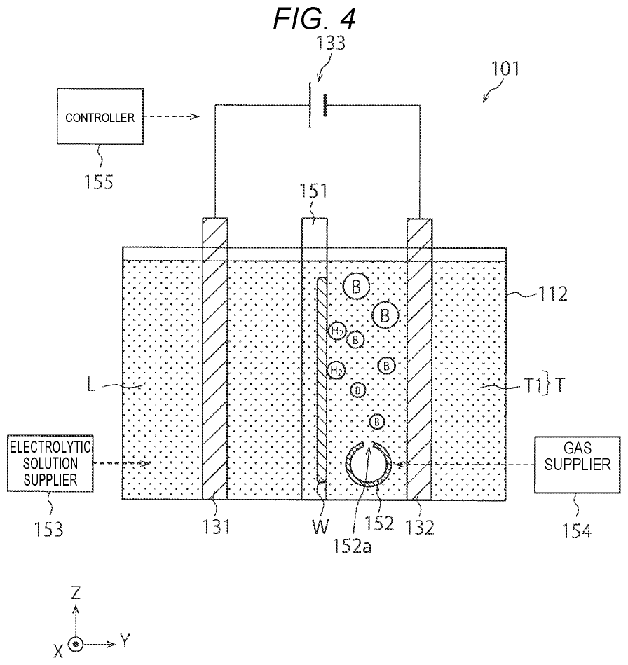

FIG. 4 is an enlarged cross-sectional view showing the structure of the substrate processing apparatus 101 according to the first embodiment.

FIG. 4 shows the above-mentioned inner container 112, the electrode 131, the electrode 132, the electric circuit 133, and the storage tank T (inner tank T1). As shown in FIG. 4, the substrate processing apparatus 101 further includes a holder 151, a bubbler tube 152, an electrolytic solution supplier 153, a gas supplier 154, and a controller 155. The bubbler tube 152 includes a plurality of openings 152a. FIG. 4 shows one of these openings 152a. The bubbler tube 152 and the gas supplier 154 are examples of the bubble supplier, and the bubbler tube 152 is an example of the tube.

FIG. 4 further shows an electrolytic solution L accommodated in the inner tank T1. The electrolytic solution L corresponds to the electrolytic solution described above. The electrolytic solution L is, for example, a hydrogen fluoride (HF) aqueous solution.

The holder 151 is configured with the lower holder 121 and the upper holder 122a described above, and holds the plurality of substrates W in the inner tank T1. FIG. 4 shows one of these substrates W. The substrate W illustrated in FIG. 1 has a quadrangular planar shape, while the substrate W illustrated in FIG. 4 has a circular planar shape. The substrate W illustrated in FIG. 4 is, for example, a semiconductor wafer such as a silicon (Si) wafer.

In FIG. 4, the electrode 131 is an anode, the electrode 132 is a cathode, and a porous layer is formed on the surface of each substrate W on the side of the electrode 132 by the anodizing method. The porous layer is formed, for example, by making a material layer formed in advance on the surface of each substrate W on the side of the electrode 132 porous. When the material layer is a polysilicon layer (semiconductor layer), the porous layer is a porous polysilicon layer (porous semiconductor layer). The material layer is an example of a first layer. Meanwhile, the porous layer may be formed in each substrate W by, for example, making a part of each substrate W porous near the surface on the side of the electrode 132 of each substrate W.

In the present embodiment, gas is generated by an anodic formation reaction when forming the porous layer, and bubbles containing the gas are generated in the electrolytic solution L. The gas is, for example, H₂ (hydrogen) gas. When the bubbles generated by the anodic formation reaction adhere to the substrate W as shown in FIG. 4, the bubbles may hinder the formation of the porous layer. The reason is considered to be that the bubbles hinder the contact between the material layer and the electrolytic solution L and inhibit the anodic formation reaction. As a result, an in-plane uniformity of a film thickness and a porosity of the porous layer may deteriorate. The bubble is an example of a second bubble.

The bubbler tube 152 is a tube for bubbling, and generates the bubbles in the electrolytic solution L from each opening 152a to supply the bubbles to the surface of each substrate W on the side of electrode 132. The bubbler tube 152 shown in FIG. 4 is disposed in the inner tank T1 and is disposed on the side of the electrode 132 with respect to the holder 151. Therefore, the bubbler tube 152 shown in FIG. 4 is disposed between the holder 151 and the electrode 132. The bubbles generated from the bubbler tube 152 are indicated by reference symbol B in FIG. 4. The bubbles generated from the bubbler tube 152 contain, for example, air, H₂ gas, N₂ (nitrogen) gas, or rare gas. The rare gas is, for example, argon (Ar) gas. This bubble is an example of the first bubble.

In FIG. 4, the surface of the substrate W on the side of the electrode 132 faces a +Y direction, and the surface of the substrate W on the side of the electrode 131 faces a −Y direction. Furthermore, the bubbler tube 152 extends in the X direction, and the opening 152a faces the +Z direction (that is, upward). In FIG. 4, the bubbler tube 152 and the opening 152a thereof are disposed near the lower end of the substrate W among the upper end and the lower end of the substrate W. Therefore, the bubbles supplied from the opening 152a into the electrolytic solution L rise in the electrolytic solution L and reach the surface of the substrate W on the side of electrode 132. According to the present embodiment, it is possible to release the bubbles generated by the anodic formation reaction and adhering to the substrate W from the substrate W by the bubbles from the bubbler tube 152.

The bubbles adhering to the substrate W are released from the substrate W by, for example, coalescence with the bubbles from the bubbler tube 152. In this case, it is considered that buoyancy of bubbles after the coalescence is larger than buoyancy of bubbles before the coalescence, and the bubbles are released from the substrate W by the buoyancy and reach a liquid surface of the electrolytic solution L. In addition, the bubbles adhering to the substrate W are released from the substrate W by colliding with, for example, the bubbles from the bubbler tube 152. In this case, it is considered that the bubbles adhering to the substrate W are released by the bubbles from the bubbler tube 152 like billiard balls, and the bubbles are detached from the substrate W and reach the liquid surface of the electrolytic solution L. The mechanism by which the bubbles are released from the substrate W may be either of the coalescence and the collision or may be other mechanism.

The substrate processing apparatus 101 of the present embodiment forms the porous layer by the electrodes 131 and 132 while supplying the bubbles from the bubbler tube 152 into the electrolytic solution L. Accordingly, the bubbles generated during the formation of the porous layer and adhering to the substrate W can be released from the substrate W by the bubbles from the bubbler tube 152.

The electrolytic solution supplier 153 supplies the electrolytic solution L into the storage tank T. The electrolytic solution supplier 153 of the present embodiment circulates the electrolytic solution L in the substrate processing apparatus 101 by supplying the electrolytic solution L discharged from the storage tank T again into the storage tank T. In the present embodiment, an additive such as a surfactant or an alcohol (for example, IPA) is not added to the electrolytic solution L. The reason is that the bubbles adhering to the substrate W can be released from the substrate W by the bubbles from the bubbler tube 152 regardless of an action of the additive.

The gas supplier 154 supplies the gas to the bubbler tube 152 to generate the bubbles from the bubbler tube 152. For example, it is desirable that the gas has a low solubility in the electrolytic solution L. As a result, it is possible to prevent the gas from being dissolved in the electrolytic solution L. In addition, the gas may have a high or low affinity with gas generated by the anodic formation reaction, for example. By increasing the affinity, it is possible to easily cause the coalescence of the bubbles. By reducing the affinity, it is possible to easily cause the collision between the bubbles.

The controller 155 controls various operations of the substrate processing apparatus 101. For example, the controller 155 controls the operation of the electric circuit 133, the holder 151, the electrolytic solution supplier 153, the gas supplier 154, and the like to perform the anodizing method.

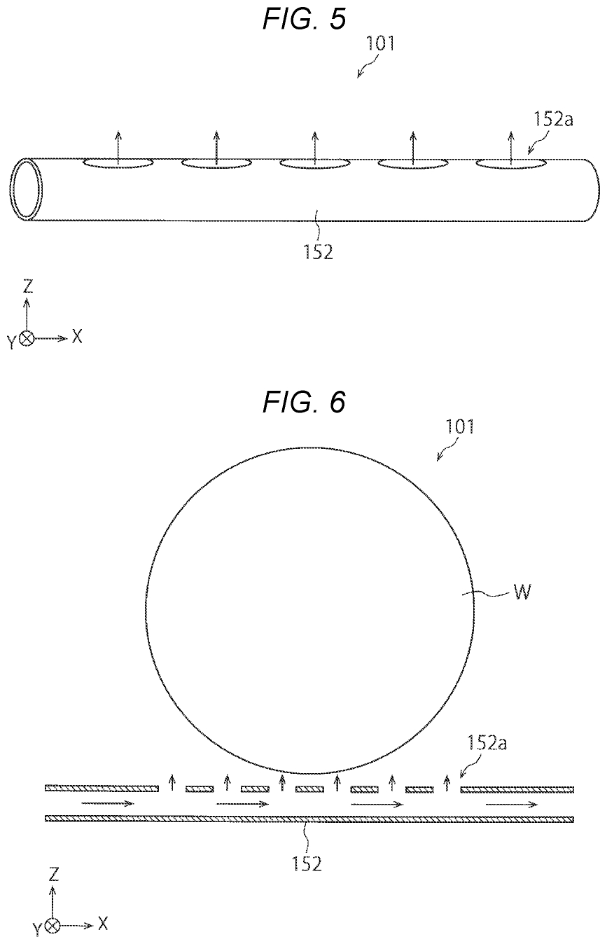

FIG. 5 is a perspective view showing a shape of the bubbler tube 152 of the first embodiment.

FIG. 5 shows a bubbler tube 152 extending in the X direction and a plurality of openings 152a provided in the bubbler tube 152. The bubbler tube 152 may extend in a direction other than the X direction. In addition, the number of openings 152a of the bubbler tube 152 may be any number. In addition, each of the openings 152a of the bubbler tube 152 may face a direction other than the +Z direction, or may have a shape other than a circular shape. In addition, the bubbler tube 152 may have an opening 152a that is movable in the inner tank T1, or may have an opening 152a that is openable and closable in the inner tank T1. In addition, the bubbler tube 152 may be a part of the inner container 112, the partition wall 113, or the holder 151.

FIG. 6 is a cross-sectional view showing a shape of the bubbler tube 152 of the first embodiment.

In the same manner as in FIG. 5, FIG. 6 shows the bubbler tube 152 extending in the X direction and the plurality of openings 152a provided in the bubbler tube 152. The openings 152a are used to supply the bubbles to different positions on the same substrate W. The number of openings 152a for supplying the bubbles to one substrate W may be any number. In addition, in the substrate processing apparatus 101 of the present embodiment, N pieces of the substrate W may be supplied with the bubbles by N pieces of the bubbler tube 152, or N pieces of the substrate W may be supplied with the bubbles by one bubbler tube 152 (N is an integer of 2 or more).

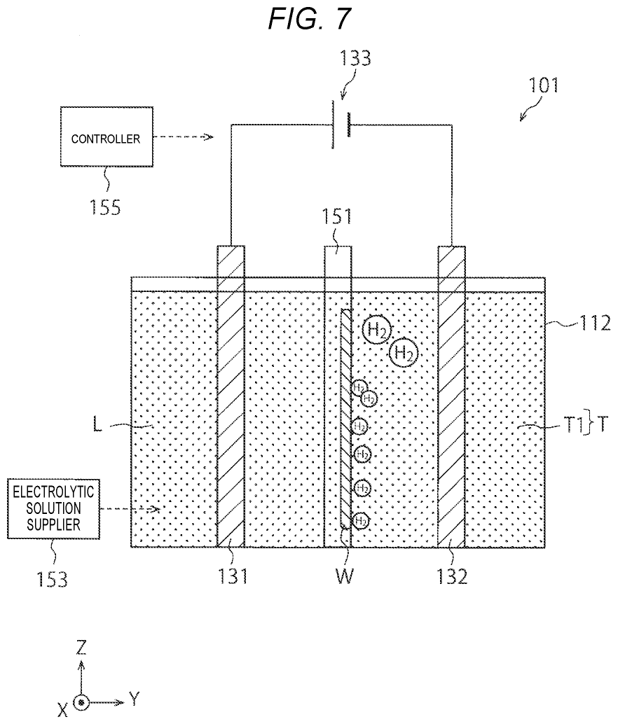

FIG. 7 is a cross-sectional view showing a structure of the substrate processing apparatus 101 of a comparative example of the first embodiment.

The substrate processing apparatus 101 of the comparative example (FIG. 7) has the same structure as the substrate processing apparatus 101 of the first embodiment (FIG. 4), but does not include the bubbler tube 152 and the gas supplier 154. Therefore, in FIG. 7, a large number of the bubbles generated by the anodic formation reaction are adhered to the surface of the substrate W during the anodic formation reaction.

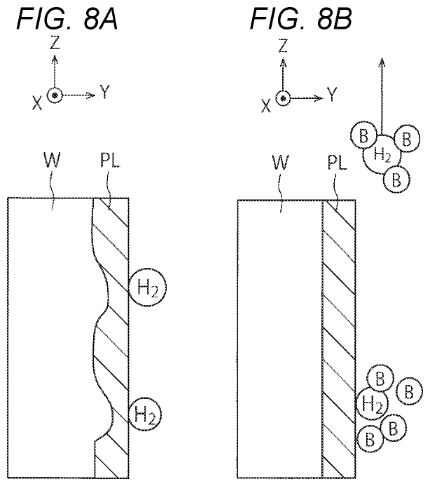

FIGS. 8A and 8B are cross-sectional views for comparing the first embodiment with the comparative example.

FIG. 8A shows the substrate W and a porous layer PL formed on the surface of the substrate W in the comparative example. The porous layer PL of FIG. 8A is formed in the substrate W by making a part of the substrate W porous. In FIG. 8A, the bubbles generated by the anodic formation reaction are adhered to the surface of the substrate W. The bubbles hinder the contact between the substrate W and the electrolytic solution L and inhibit the anodic formation reaction. As a result, as shown in FIG. 8A, the in-plane uniformity of the film thickness and the porosity of the porous layer PL deteriorates.

FIG. 8B shows the substrate W and the porous layer PL formed on the surface of the substrate W in the first embodiment. The porous layer PL of FIG. 8B is also formed in the substrate W by making a part of the substrate W porous. In the present embodiment, the bubbler tube 152 generates the bubbles in the electrolytic solution L from each of the openings 152a to supply the bubbles to the surface of the substrate W. Therefore, according to the present embodiment, the bubbles generated by the anodic formation reaction and adhering to the substrate W can be released from the substrate W by the bubbles from the bubbler tube 152. As a result, as shown in FIG. 8B, it is possible to improve the in-plane uniformity of the film thickness and the porosity of the porous layer PL.

It is possible that the contents described with reference to FIG. 8A and FIG. 8B are applied even when the porous layer PL is formed by making the material layer formed in advance on the surface of the substrate W porous.

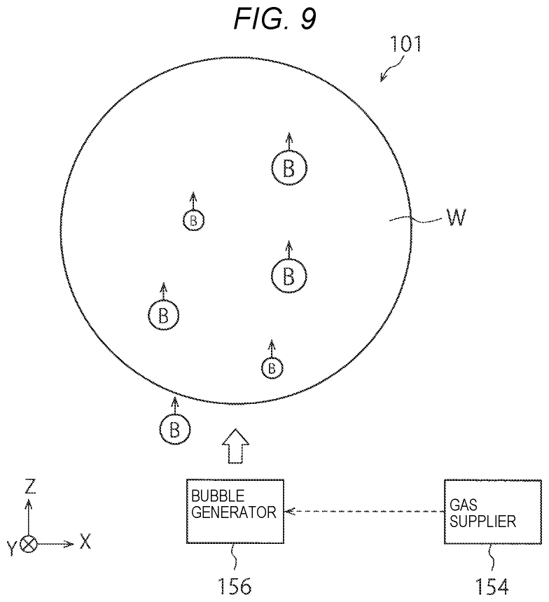

FIG. 9 is a cross-sectional view showing the structure of the substrate processing apparatus 101 according to a first modification example of the first embodiment.

The substrate processing apparatus 101 of the present modification example includes the bubble generator 156 instead of the bubbler tube 152. The bubble generator 156 and the gas supplier 154 of the present modification example are examples of the bubble supplier.

The bubble generator 156 generates the bubbles in the electrolytic solution L and supplies the bubbles to the surface of the substrate W on the side of the electrode 132, in the same manner as the bubbler tube 152. The bubbles contain, for example, air, H₂ gas, N₂ gas, or rare gas. The bubble generator 156 is, for example, a member having a different shape from the tube and having the opening for generating the bubbles.

In FIG. 9, the bubbles supplied from the bubble generator 156 into the electrolytic solution L reach the surface of the substrate W on the electrode 132 side by rising in the electrolytic solution L. According to the present modification example, the bubbles generated by the anodic formation reaction and adhering to the substrate W can be released from the substrate W by the bubbles from the bubble generator 156.

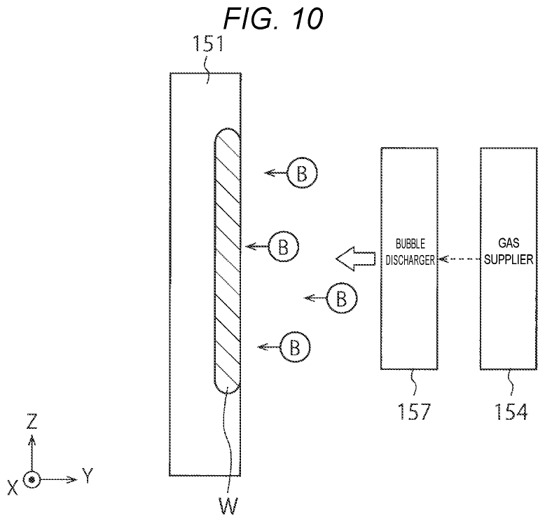

FIG. 10 is a cross-sectional view showing a structure of a substrate processing apparatus 101 according to a second modification example of the first embodiment.

The substrate processing apparatus 101 of the present modification example includes the bubble discharger 157 instead of the bubbler tube 152. The bubble discharger 157 and the gas supplier 154 of the present modification example are examples of the bubble supplier.

The bubble discharger 157 supplies the bubbles to the surface of the substrate W on the side of the electrode 132 by discharging the bubbles toward the surface of the substrate W on the side of the electrode 132. The bubbles contain, for example, air, H₂ gas, N₂ gas, or rare gas. The bubble discharger 157 is, for example, a nozzle that discharges the bubbles.

According to the present modification example, the bubbles generated by the anodic formation reaction and adhering to the substrate W can be released from the substrate W by the bubbles from the bubble discharger 157. According to the present modification example, the bubble can reach the substrate W with the bubbles by discharging the bubbles instead of using buoyancy. Accordingly, the bubble discharger 157 can be disposed other than near the lower end of the substrate W.

As described above, the substrate processing apparatus 101 of the present embodiment generates the bubbles in the electrolytic solution L from the bubbler tube 152 or the like and supplies the bubbles to the surface of the substrate W. Therefore, according to the present embodiment, it is possible to suitably form the porous layer PL on the surface of the substrate W. For example, the bubbles generated by the anodic formation reaction and adhering to the substrate W can be released from the substrate W by the bubbles from the bubbler tube 152 or the like. As a result, it is possible to improve the in-plane uniformity of the film thickness and the porosity of the porous layer PL.

### Second Embodiment

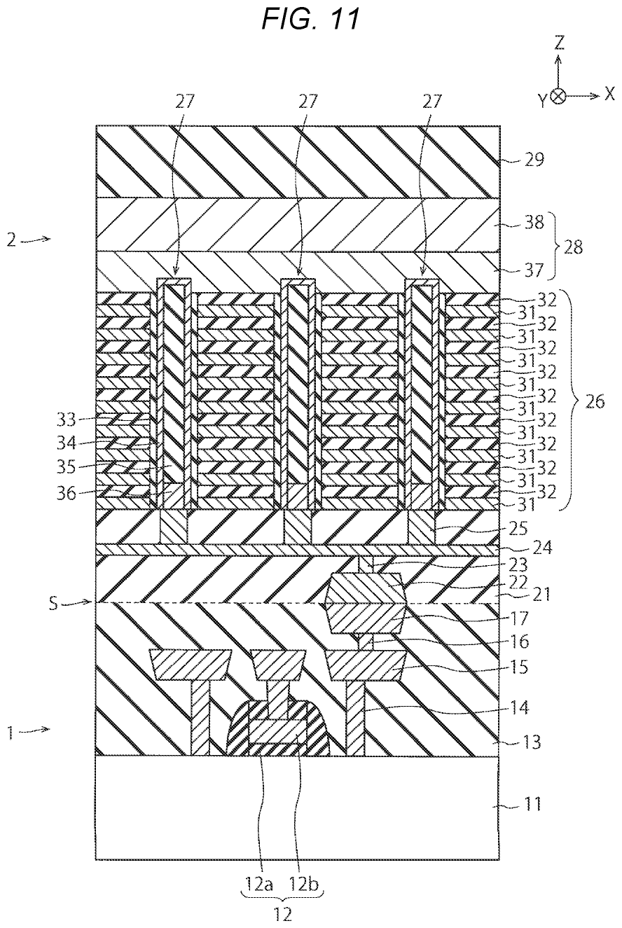

FIG. 11 is a cross-sectional view showing a structure of a semiconductor device according to a second embodiment. The semiconductor device of FIG. 11 is, for example, a three-dimensional flash memory.

The semiconductor device of FIG. 11 includes a circuit area 1 including a Complementary Metal Oxide Semiconductor (CMOS) circuit and an array area 2 including a memory cell array. The memory cell array includes a plurality of memory cells that stores data, and the CMOS circuit includes a peripheral circuit that controls an operation of the memory cell array. The semiconductor device of FIG. 11 is manufactured, for example, by bonding a circuit wafer including the circuit area 1 and an array wafer including the array area 2, as will be described later. A bonding surface between the circuit area 1 and the array area 2 is indicated by reference symbol S.

In FIG. 11, the circuit area 1 includes a substrate 11, a transistor 12, an interlayer insulating film 13, a plurality of contact plugs 14, a wiring layer 15 including a plurality of wirings, a via plug 16, and a metal pad 17. FIG. 11 shows three of the plurality of wirings in the wiring layer 15 and three contact plugs 14 provided under the wirings. The substrate 11 is an example of a second substrate.

In FIG. 11, the array area 2 includes an interlayer insulating film 21, a metal pad 22, a via plug 23, a wiring layer 24 including a plurality of wirings, a plurality of contact plugs 25, a stacked film 26, and a plurality of columnar portions 27, a source layer 28, and an insulating film 29. FIG. 11 shows one of the plurality of wirings in the wiring layer 24, three contact plugs 25 provided on the wiring, and three columnar portions 27.

Further, as shown in FIG. 11, the stacked film 26 includes a plurality of electrode layers 31 and a plurality of insulating layers 32. Each columnar portion 27 includes a memory insulating film 33, a channel semiconductor layer 34, a core insulating film 35, and a core semiconductor layer 36. The source layer 28 includes a semiconductor layer 37 and a metal layer 38.

Hereinafter, the structure of the semiconductor device according to the present embodiment will be described with reference to FIG. 11.

The substrate 11 is, for example, a semiconductor substrate such as a Si substrate. The transistor 12 includes a gate insulating film 12a and a gate electrode 12b formed in order on the substrate 11, and a source diffusion layer and a drain diffusion layer (not shown) formed in the substrate 11. The transistor 12 constitutes, for example, the above-described CMOS circuit. The interlayer insulating film 13 is formed on the substrate 11 to cover the transistor 12. The interlayer insulating film 13 is, for example, a SiO₂ film (silicon oxide film) or a stacked film including the SiO₂ film and other insulating film.

The contact plugs 14, the wiring layer 15, the via plug 16, and the metal pad 17 are formed in the interlayer insulating film 13. Specifically, the contact plugs 14 are disposed on the substrate 11 and on the gate electrode 12b of the transistor 12. In FIG. 11, the contact plugs 14 on the substrate 11 are provided on the source diffusion layer and the drain diffusion layer (not shown) of the transistor 12. The wiring layer 15 is disposed on the contact plugs 14, and the via plug 16 is disposed on the wiring layer 15. The metal pad 17 is disposed on the via plug 16 above the substrate 11. The metal pad 17 is, for example, a metal layer including a Cu (copper) layer.

The interlayer insulating film 21 is formed on the interlayer insulating film 13. The interlayer insulating film 21 is, for example, a SiO₂ film or a stacked film including a SiO₂ film and other insulating film.

The metal pad 22, the via plug 23, the wiring layer 24, and the contact plugs 25 are formed in the interlayer insulating film 21. Specifically, the metal pad 22 is disposed on the metal pad 17 above the substrate 11. The metal pad 22 is, for example, a metal layer including a Cu layer. The via plug 23 is disposed on the metal pad 22, and the wiring layer 24 is disposed on the via plug 23. FIG. 11 shows one of the plurality of wirings in the wiring layer 24, and the wiring functions as, for example, a bit line. The contact plugs 25 are disposed on the wiring layer 24.

The stacked film 26 is provided on the interlayer insulating film 21, and includes the plurality of electrode layers 31 and the plurality of insulating layers 32 alternately stacked in the Z direction. The electrode layer 31 is, for example, a metal layer including a W (tungsten) layer, and functions as a word line. The insulating layer 32 is, for example, a SiO₂ film.

Each columnar portion 27 is provided in the stacked film 26, and includes the memory insulating film 33, the channel semiconductor layer 34, the core insulating film 35, and the core semiconductor layer 36. The memory insulating film 33 is formed on a side surface of the stacked film 26 and has a tubular shape extending in the Z direction. The channel semiconductor layer 34 is formed on a side surface of the memory insulating film 33 and has a tubular shape extending in the Z direction. The core insulating film 35 and the core semiconductor layer 36 are formed on a side surface of the channel semiconductor layer 34 and have a rod-like shape extending in the Z direction. Specifically, the core semiconductor layer 36 is disposed on the contact plug 25, and the core insulating film 35 is disposed on the core semiconductor layer 36.

As will be described later, the memory insulating film 33 includes, for example, a block insulating film, a charge storage layer, and a tunnel insulating film in order. The block insulating film is, for example, a SiO₂ film. The charge storage layer is, for example, a SiN film (silicon nitride film). The tunnel insulating film is, for example, a SiO₂ film or a SiON film (silicon oxynitride film). The channel semiconductor layer 34 is, for example, a polysilicon layer. The core insulating film 35 is, for example, a SiO₂ film. The core semiconductor layer 36 is, for example, a polysilicon layer. Each memory cell in the above-described memory cell array includes the channel semiconductor layer 34, the charge storage layer, the electrode layer 31, and the like.

The channel semiconductor layer 34 and the core semiconductor layer 36 in each columnar portion 27 are electrically connected to the metal pad 22 via the contact plug 25, the wiring layer 24, and the via plug 23. Therefore, the memory cell array in the array area 2 is electrically connected to the peripheral circuit in the circuit area 1 via the metal pad 22 and the metal pad 17. Therefore, it is possible to control the operation of the memory cell array by the peripheral circuit.

The source layer 28 includes the semiconductor layer 37 and the metal layer 38 formed in order on the stacked film 26 and the columnar portion 27 and functions as a source line. In the present embodiment, the channel semiconductor layer 34 of each columnar portion 27 is exposed from the memory insulating film 33, and the semiconductor layer 37 is formed directly on the channel semiconductor layer 34. Further, the metal layer 38 is formed directly on the semiconductor layer 37. Therefore, the source layer 28 is electrically connected to the channel semiconductor layer 34 and the core semiconductor layer 36 of each columnar portion 27. The semiconductor layer 37 is, for example, a polysilicon layer. The metal layer 38 includes, for example, a W layer, a Cu layer, or an Al (aluminum) layer.

The insulating film 29 is formed on the source layer 28. The insulating film 29 is, for example, a SiO₂ film.

FIG. 12 is an enlarged cross-sectional view showing the structure of the semiconductor device according to the second embodiment.

FIG. 12 shows three electrode layers 31 and three insulating layers 32 provided in the stacked film 26, and one columnar portion 27 provided in the stacked film 26. As described above, the memory insulating film 33 in the columnar portion 27 includes a block insulating film 33a, a charge storage layer 33b, and a tunnel insulating film 33c, which are formed on the side surface of the stacked film 26 in order. The block insulating film 33a is, for example, a SiO₂ film. The charge storage layer 33b is, for example, a SiN film. The tunnel insulating film 33c is, for example, a SiO₂ film or a SION film.

Meanwhile, each electrode layer 31 includes a barrier metal layer 31a and an electrode material layer 31b. The barrier metal layer 31a is, for example, a TiN film (titanium nitride film). The electrode material layer 31b is, for example, a W layer. As shown in FIG. 12, each electrode layer 31 according to the present embodiment is formed on a lower surface of the upper insulating layer 32, an upper surface of the lower insulating layer 32, and a side surface of the block insulating film 33a via a block insulating film 39. The block insulating film 39 is, for example, an Al₂O₃ film (aluminum oxide film), and functions as the block insulating film of each memory cell together with the block insulating film 33a.

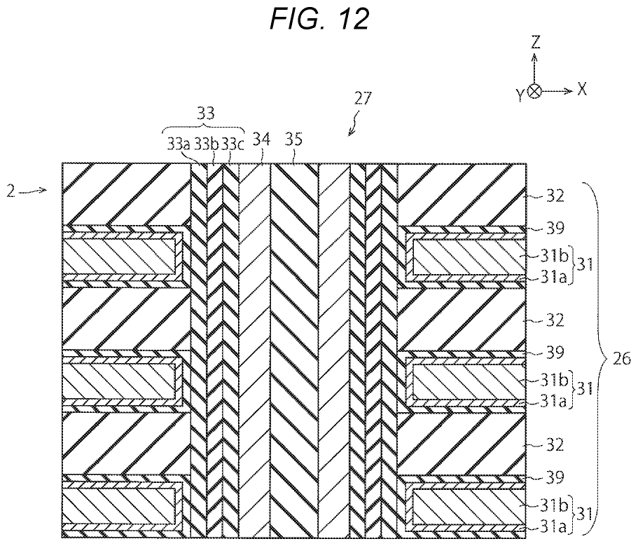

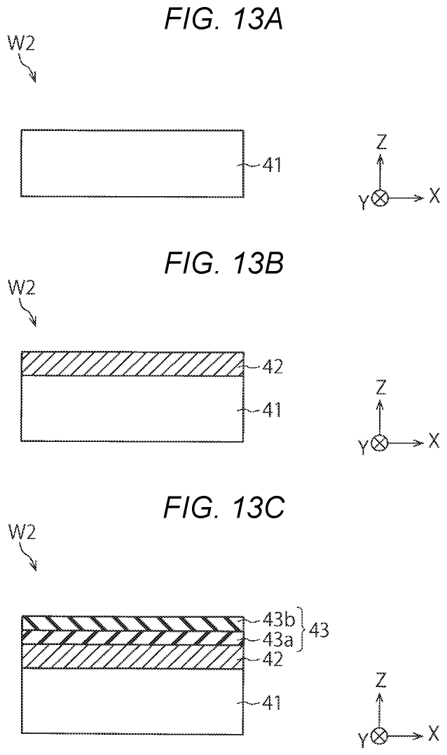

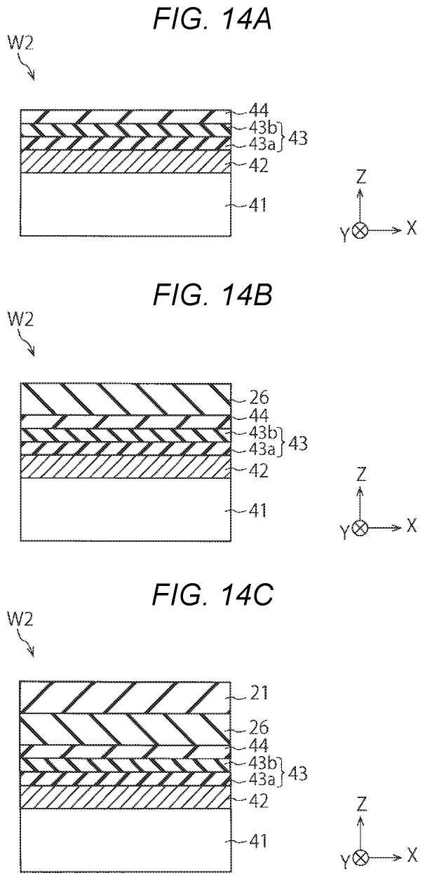

FIGS. 13A to 13C and FIGS. 14A to 14C are cross-sectional views showing a method for manufacturing a semiconductor device according to the second embodiment. The semiconductor device according to the present embodiment is manufactured by bonding a circuit wafer W1 and an array wafer W2, which will be described later. The circuit wafer W1 is used to manufacture the circuit area 1, and the array wafer W2 is used to manufacture the array area 2. The circuit wafer W1 and the array wafer W2 have a disk shape.

First, a substrate 41 for the array wafer W2 is prepared (FIG. 13A). The substrate 41 is, for example, a semiconductor substrate such as a Si substrate. The substrate 41 corresponds to the substrate W of the first embodiment. The substrate 41 is an example of a first substrate.

Next, a porous layer 42 is formed on the substrate 41 (FIG. 13B). The porous layer 42 is, for example, a porous semiconductor layer such as a porous polysilicon layer. The porous layer 42 is formed, for example, by forming a material layer for forming the porous layer 42 on the substrate 41 and forming voids in the material layer. That is, the porous layer 42 is formed by making the material layer porous. When the material layer is a polysilicon layer (semiconductor layer), the porous layer 42 is a porous polysilicon layer (porous semiconductor layer). The material layer is made porous by, for example, setting the substrate 41 on which the material layer is formed in the substrate processing apparatus 101 described above and applying the anodizing method to the material layer. As a result, the material layer is changed to the porous layer 42 by the anodizing method. The material layer is an example of a first layer. The porous layer 42 may be formed in the substrate 41 or may be formed on the substrate 41 via other layer.

Next, a cap insulating film 43 is formed on the porous layer 42 (FIG. 13C). The cap insulating film 43 includes an insulating film 43a formed on the porous layer 42 and an insulating film 43b formed on the insulating film 43a. The insulating film 43a is, for example, a SiO₂ film. The insulating film 43b is, for example, a SiN film.

Next, an insulating film 44 is formed on the cap insulating film 43 (FIG. 14A). The insulating film 44 is, for example, a SiO₂ film.

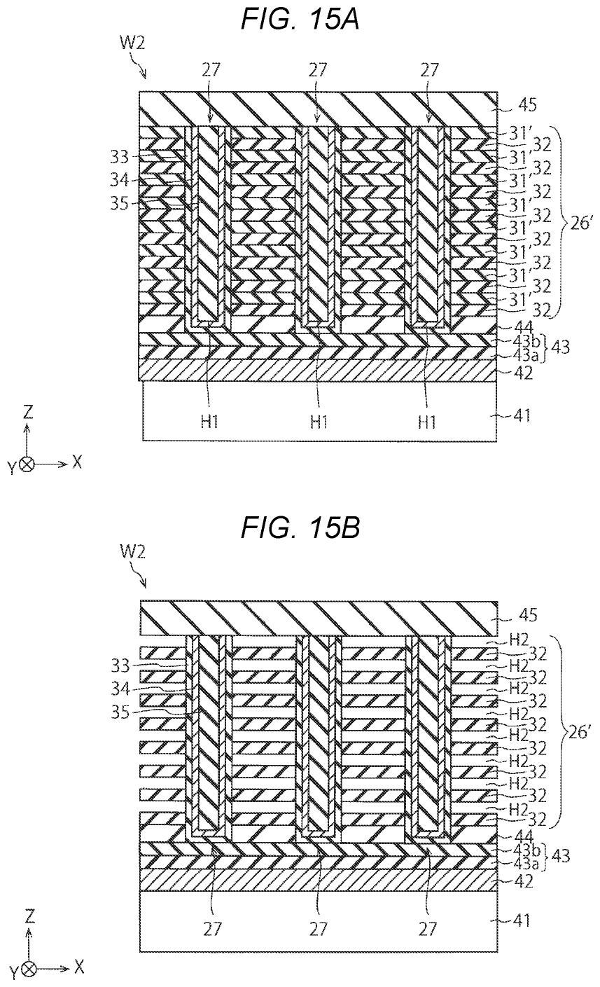

Next, the stacked film 26 and the interlayer insulating film 21 are formed on the insulating film 44 in order (FIG. 14B and FIG. 14C). The details of the stacked film 26 and the interlayer insulating film 21 are as described above with reference to FIG. 11. FIG. 14B and FIG. 14C schematically show structures of the stacked film 26 and the interlayer insulating film 21. A step shown in FIG. 14B and FIG. 14C and subsequent steps will be described later with reference to FIGS. 15A and 15B to FIGS. 19A and 19B.

FIGS. 15A and 15B to FIGS. 19A and 19B are cross-sectional views showing the details of the method for manufacturing the semiconductor device according to the second embodiment.

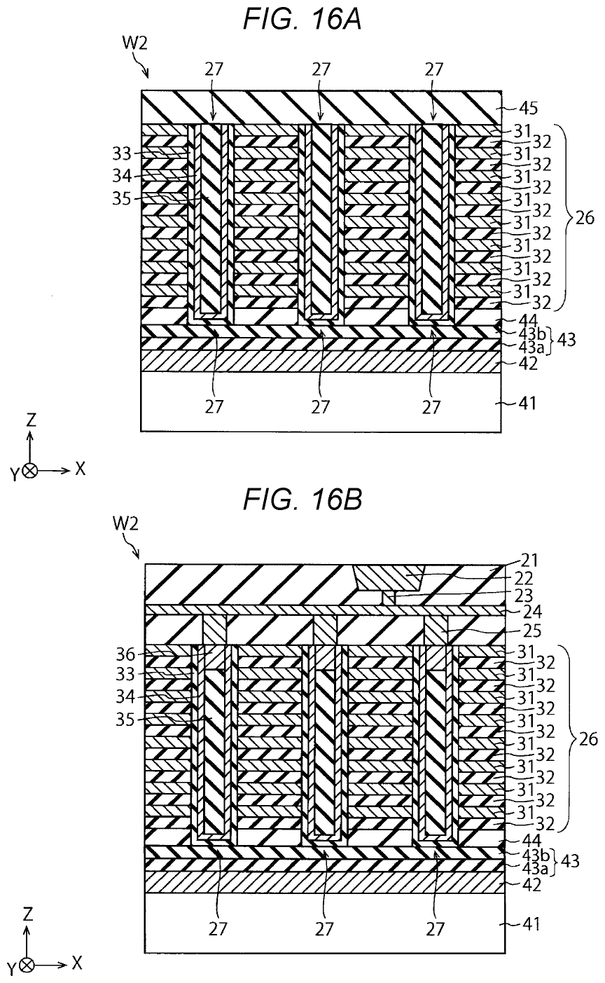

FIG. 15A to FIG. 16B show the details of the step shown in FIG. 14B and FIG. 14C. First, the insulating film 44 is formed on the cap insulating film 43, and a stacked film 26′ is formed on the insulating film 44 (FIG. 15A). The stacked film 26′ is a film for forming the stacked film 26 by a replacement treatment. The stacked film 26′ is formed to alternately include a plurality of sacrificial layers 31′ and the plurality of insulating layers 32. The sacrificial layer 31′ is, for example, a SiN film.

Next, a plurality of memory holes H1 penetrating the stacked film 26′ and the insulating film 44 are formed, and the memory insulating film 33, the channel semiconductor layer 34, and the core insulating film 35 are sequentially formed in each of the memory holes H1 (FIG. 15A). As a result, the plurality of columnar portions 27 extending in the Z direction are formed in the memory holes H1. The memory insulating film 33 is formed by sequentially forming the block insulating film 33a, the charge storage layer 33b, and the tunnel insulating film 33c in each memory hole H1 (see FIG. 12).

Next, an insulating film 45 is formed on the stacked film 26′ and the columnar portions 27 (FIG. 15A). The insulating film 45 is, for example, a SiO₂ film.

Next, a slit (not shown) penetrating the insulating film 45 and the stacked film 26′ is formed, and the sacrificial layer 31′ is removed by wet etching using the slit (FIG. 15B). As a result, a plurality of cavities H2 are formed between the insulating layers 32 in the stacked film 26′.

Next, the plurality of electrode layers 31 are formed in the cavities H2 from the slits (FIG. 16A). As a result, the stacked film 26, which includes the plurality of electrode layers 31 and the plurality of insulating layers 32 alternately, is formed between the insulating film 44 and the insulating film 45 (replacement treatment). Further, a structure, in which the plurality of columnar portions 27 penetrate the stacked film 26, is formed above the substrate 41. When the electrode layer 31 is formed in each cavity H2, the block insulating film 39, the barrier metal layer 31a, and the electrode material layer 31b are sequentially formed in each cavity H2 (see FIG. 12).

Next, the insulating film 45 is removed, a part of the core insulating film 35 in each columnar portion 27 is removed, and the core semiconductor layer 36 is embedded in an area from which a part of the core insulating film 35 is removed (FIG. 16B). As a result, each columnar portion 27 is processed into a structure including the memory insulating film 33, the channel semiconductor layer 34, the core insulating film 35, and the core semiconductor layer 36.

Next, the interlayer insulating film 21, the metal pad 22, the via plug 23, the wiring layer 24, and the plurality of contact plugs 25 are formed on the stacked film 26 and the columnar portion 27 (FIG. 16B). At this time, these contact plugs 25 are respectively formed on the core semiconductor layers 36 of the corresponding columnar portion 27, and the wiring layer 24, the via plug 23, and the metal pad 22 are sequentially formed on the contact plugs 25. FIG. 16B shows the same state as shown in FIG. 14C.

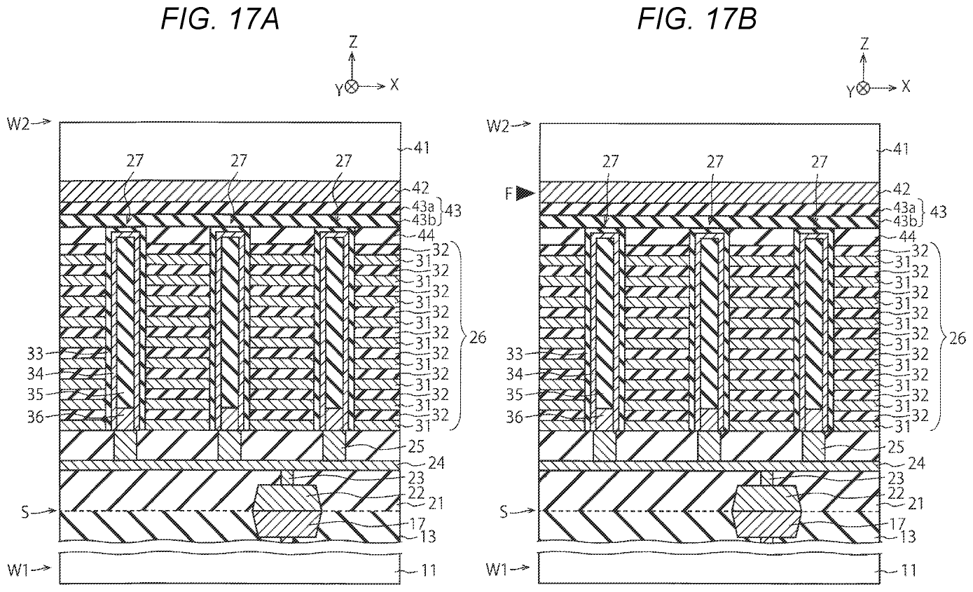

FIG. 17A shows a step (bonding step) of bonding the circuit wafer W1 and the array wafer W2. The circuit wafer W1 shown in FIG. 17A is manufactured by preparing the substrate 11 and forming the transistor 12, the interlayer insulating film 13, the plurality of contact plugs 14, the wiring layer 15, the via plug 16, and the metal pad 17 on the substrate 11 (see FIG. 11). At this time, the transistor 12 is formed on the substrate 11, and these contact plugs 14 are formed on the substrate 11 and the transistor 12. Further, the wiring layer 15, the via plug 16, and the metal pad 17 are sequentially formed on the contact plugs 14.

Next, an orientation of the array wafer W2 is reversed, and the circuit wafer W1 and the array wafer W2 are bonded by mechanical pressure (FIG. 17A). As a result, the interlayer insulating film 13 and the interlayer insulating film 21 are adhered to each other. Next, the circuit wafer W1 and the array wafer W2 are annealed (FIG. 17A). As a result, the metal pad 17 and the metal pad 22 are joined. In this manner, the substrate 11 and the substrate 41 are bonded so as to sandwich the interlayer insulating films 13 and 21, the stacked film 26, the insulating film 44, the cap insulating film 43, and the porous layer 42, and the substrate 41 is stacked above the substrate 11. Each metal pad 22 is disposed on the corresponding metal pad 17.

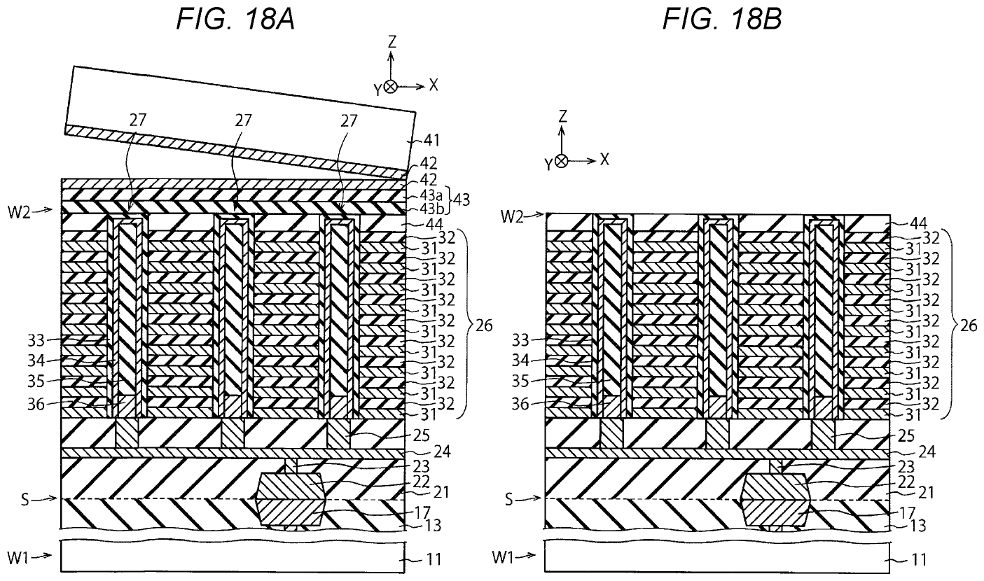

Next, a physical force F is applied to the array wafer W2 by a blade or a water jet (FIG. 17B). For example, a force F is applied to the cross section of the porous layer 42. As a result, the porous layer 42 is broken. As a result, the substrate 11 and the substrate 41 can be separated from each other (FIG. 18A). In FIG. 17A and FIG. 18A, the force F is applied to the cross section of the porous layer 42, and the porous layer 42 is fractured. Therefore, the substrate 11 and the substrate 41 are separated from each other at the position of the porous layer 42. As a result, a part of the porous layer 42 remains on the surface of the substrate 41, and the remaining portion of the porous layer 42 remains on the surface of the substrate 11. Further, the above-described memory cell array and the CMOS circuit also remain on the front surface of the substrate 11. The porous layer 42 is divided into a portion on the side of the substrate 41 and a portion on the side of the substrate 11. The former portion is an example of a first portion, and the latter portion is an example of a second portion. The porous layer 42 functions as a separation layer (peeling layer) for separating (peeling) the substrate 41 from the substrate 11.

The porous layer 42 of the present embodiment includes a large number of voids and thus is likely to crack. Therefore, the porous layer 42 can be broken by applying the force F to the porous layer 42. The substrate 11 and the substrate 41 may be separated by breaking a material other than the porous layer 42 (for example, the cap insulating film 43) instead of the porous layer 42 or together with the porous layer 42. In this case, the force F may be applied to the material.

In the present embodiment, the substrate 41 above the substrate 11 is removed by peeling the substrate 41 from the substrate 11 instead of scraping the substrate 41. As a result, it is possible to prevent damage to the substrate 41, and it is possible to reuse the substrate 41. In the present embodiment, after the substrate 11 and the substrate 41 are separated from each other, the porous layer 42 and the like remaining on the front surface of the substrate 41 are removed, and the substrate 41 is reused in the bonding step shown in FIG. 17A. Therefore, it is possible to avoid waste of using a large number of substrates 41. The force F applied to porous layer 42 may be applied mechanically like the blade, may be applied fluidly like the water jet, or may be applied in other ways.

Next, the porous layer 42 and the cap insulating film 43 above the substrate 11 are removed (FIG. 18B). As a result, the insulating film 44 and each columnar portion 27 are exposed above the substrate 11. A step shown in FIG. 18B is performed by, for example, Chemical Mechanical Polishing (CMP) or etching. In the step of FIG. 18B, the substrate 11 may be further thinned by CMP or etching.

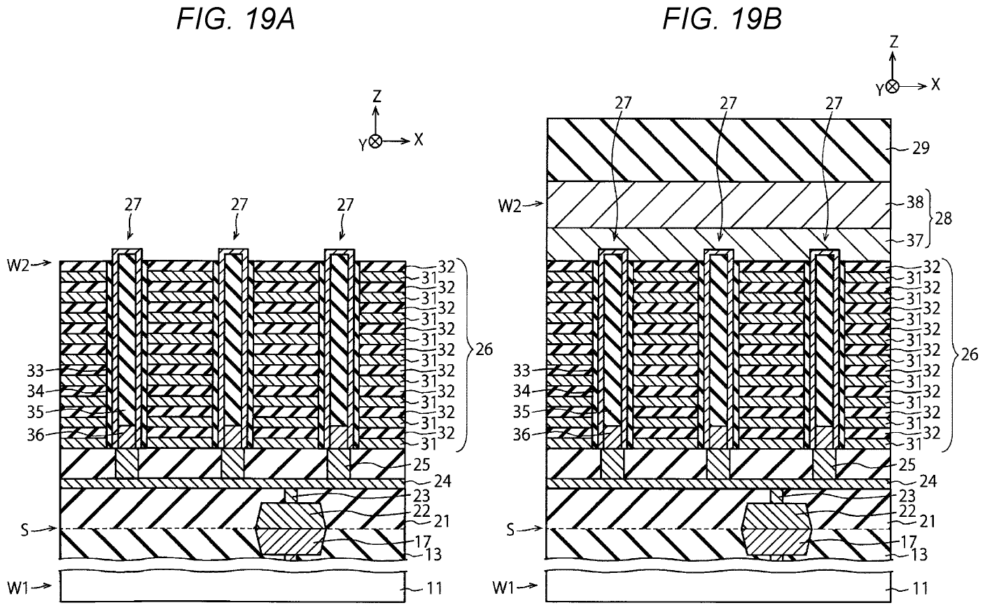

Next, the insulating film 44 or a part of the memory insulating film 33 of each columnar portion 27 is removed by etching (FIG. 19A). A portion of the memory insulating film 33 to be removed is, for example, a portion exposed from the stacked film 26. As a result, a part of the channel semiconductor layer 34 of each columnar portion 27 is exposed from the memory insulating film 33 at a position higher than the stacked film 26.

Next, the semiconductor layer 37, the metal layer 38, and the insulating film 29 are sequentially formed on the stacked film 26 and the columnar portion 27 (FIG. 19B). As a result, the source layer 28 is formed on the channel semiconductor layer 34 of each columnar portion 27 and is electrically connected to the channel semiconductor layer 34 of each columnar portion 27.

After that, the circuit wafer W1 and the array wafer W2 are cut into a plurality of chips. The chips are cut so that each chip includes the circuit area 1 and the array area 2. In this way, the semiconductor device of FIG. 11 is manufactured.

The semiconductor device according to the present embodiment may be sold in a state shown in FIG. 11 or may be sold in a state shown in FIG. 16B or FIG. 17A.

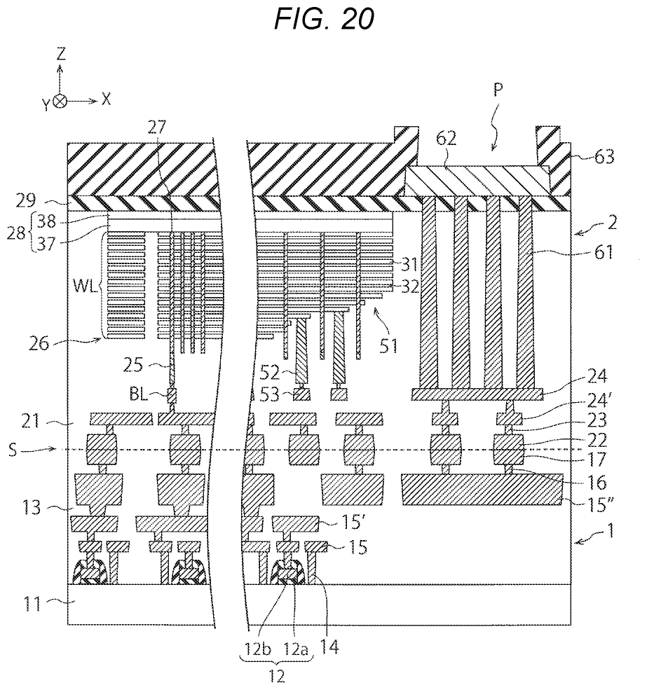

FIG. 20 is a cross-sectional view showing a structure of a semiconductor device according to another modification example of the second embodiment. The semiconductor device described with reference to FIG. 11 to FIG. 19B may have the structure shown in FIG. 11 instead of having the structure shown in FIG. 20.

The semiconductor device according to the present modification example includes a circuit area 1 and an array area 2 as the same as in the semiconductor device according to the second embodiment. In addition to the elements shown in FIG. 11, the circuit area 1 includes wiring layers 15′ and 15″ that electrically connect a wiring layer 15 and a via plug 16. In addition to the elements shown in FIG. 11, the array area 2 includes a wiring layer 24′ that electrically connects a via plug 23 and a wiring layer 24. Each of the wiring layers 15′, 15″, and 24′ includes a plurality of wirings, as the same as in the wiring layer 15 and the wiring layer 24.

FIG. 20 shows a plurality of word lines WL (electrode layers 31) in a stacked film 26, a plurality of columnar portions 27 penetrating the stacked film 26, and a step structure portion 51 of the stacked film 26. Each word line WL is electrically connected to a word wiring layer 53 by the step structure portion 51 via a contact plug 52. Each columnar portion 27 is electrically connected to a bit line BL via the contact plug 25, and is electrically connected to a source layer 28. The word wiring layer 53 and the bit line BL according to the present modification example are provided in the wiring layer 24.

The array area 2 further includes a plurality of via plugs 61 provided on the wiring layer 24, a metal pad 62 provided on the via plugs 61 and an insulating film 29, and a passivation film 63 provided on the metal pad 62 and the insulating film 29. The passivation film 63 is, for example, a stacked insulating film including a silicon oxide film, silicon nitride film, or the like, and has an opening P that exposes an upper surface of the metal pad 62. The metal pad 62 is an external connection pad of the semiconductor device according to the present modification example, and may be connected to a mounting substrate or other device via a solder ball, a metal bump, a bonding wiring, or the like.

As described above, the semiconductor device of the present embodiment is manufactured using the porous layer 42 formed by the substrate processing apparatus 101 of the first embodiment. Therefore, according to the present embodiment, it is possible to suitably form the porous layer 42 on the surface of the substrate 41. Furthermore, according to the present embodiment, the substrate 41 can be reused by peeling the substrate 41 from the substrate 11.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus comprising:
a processing tank configured to accommodate a substrate processing liquid;
a holder configured to place a first substrate in the processing tank;
an anode and a cathode configured to form a porous layer on a first surface of the first substrate; and
a bubble supplier configured to supply a first bubble to the first surface of the first substrate.

2. The substrate processing apparatus according to claim 1,
wherein the anode and the cathode form the porous layer by an anodizing method.

3. The substrate processing apparatus according to claim 1,
wherein the holder configured to hold the first substrate between the anode and the cathode.

4. The substrate processing apparatus according to claim 1,
wherein the holder configured to hold the first substrate such that the first surface of the first substrate faces a side of the cathode and a second surface of the first substrate faces a side of the anode.

5. The substrate processing apparatus according to claim 1,
wherein the porous layer is formed by making a first layer provided on the first surface of the first substrate porous.

6. The substrate processing apparatus according to claim 1,
wherein the bubble supplier configured to supply the first bubble so that a second bubble, generated during the formation of the porous layer and adhered to the first substrate, are released from the first substrate by the first bubble.

7. The substrate processing apparatus according to claim 6,
wherein the second bubble is released from the first substrate by coalescing with or colliding with the first bubble.

8. The substrate processing apparatus according to claim 6,
wherein the second bubble contains a hydrogen gas.

9. The substrate processing apparatus according to claim 1,
wherein the first bubble contains air, a hydrogen gas, a nitrogen gas, or a rare gas.

10. The substrate processing apparatus according to claim 1,
wherein the bubble supplier includes a tube having an opening, and is configured to generate the first bubble in the substrate processing liquid from the opening of the tube.

11. The substrate processing apparatus according to claim 10,
wherein the tube is disposed in the processing tank.

12. The substrate processing apparatus according to claim 10,
wherein the tube is disposed on a side of the cathode with respect to the holder.

13. The substrate processing apparatus according to claim 10,
wherein the tube is configured to generate the first bubble from the opening near the lower end of the first substrate.

14. The substrate processing apparatus according to claim 1,
wherein the bubble supplier is configured to supply the first bubble into the substrate processing liquid such that the first bubble rises in the substrate processing tank to reach the first surface of the first substrate.

15. The substrate processing apparatus according to claim 1,
wherein the bubble supplier configured to supply the first bubble to the first surface of the first substrate by discharging the first bubble toward the first surface of the first substrate.

16. A method for manufacturing a semiconductor device, the method comprising:
accommodating a substrate processing liquid in a processing tank;
placing a first substrate in the processing tank with a holder; and
forming a porous layer on a first surface of the first substrate with an anode and a cathode,
wherein the porous layer is formed while supplying a first bubble to the first surface of the first substrate by supplying the first bubble into the substrate processing liquid from a bubble supplier.

17. The method for manufacturing a semiconductor device according to claim 16,
wherein the anode and the cathode form the porous layer by an anodizing method.

18. The method for manufacturing a semiconductor device according to claim 16,
wherein the porous layer is formed by making a first layer provided on the first surface of the first substrate porous.

19. The method for manufacturing a semiconductor device according to claim 16, further comprising:
bonding the first substrate to a second substrate with the porous layer sandwiched therebetween.

20. The method for manufacturing a semiconductor device according to claim 19, further comprising:
separating the first substrate and the second substrate such that a first portion of the porous layer remains on the first substrate and a second portion of the porous layer remains on the second substrate.
